(19) United States
(12) Patent Application Publication
(10) Pub. No.: US 2017/0059637 A1
(43) Pub. Date: Mar. 2, 2017

(54) DETECTING AND ACCOUNTING FOR FAULT CONDITIONS AFFECTING ELECTRONIC DEVICES

(71) Applicant: Schlumberger Technology Corporation, Sugar Land, TX (US)

(72) Inventors: David Santoso, Sugar Land, TX (US); Burc Abdullah Simsek, Sugar Land, TX (US); Randall Paul LeBlanc, Katy, TX (US); Vladimir Rubin, Katy, TX (US); Bharat Narasimhan, Houston, TX (US)

(21) Appl. No.: 14/838,511

(22) Filed: Aug. 28, 2015

(51) Int. Cl. G01R 31/02; E21B 47/00

(52) U.S. Cl. CPC G01R 31/024; E21B 47/00

(57) ABSTRACT

Aspects of the disclosure can relate to detecting and accounting for fault conditions affecting electronic devices. In implementations, electronic devices can be coupled to one another in series with a common power line linking the electronic devices together. For example, the electronic devices can include down hole tools/equipment of a drill string. In embodiments, a system can include circuitry configured to couple a first electronic device with a second electronic device. The circuitry can detect or receive information regarding a fault condition and can set a switch to an open position, where the first electronic device and the second electronic device are electrically disconnected from one another, when a fault condition affects or is caused by the second electronic device.

### BACKGROUND INFORMATION

Oil wells are created by drilling a hole into the earth using a drilling rig that rotates a drill string (e.g., drill pipe) having a drill bit attached thereto. The drill bit, aided by the weight of pipes (e.g., drill collars) cuts into rock within the earth. Drilling fluid (e.g., mud) is pumped into the drill pipe and exits at the drill bit. The drilling fluid may be used to cool the bit, lift rock cuttings to the surface, at least partially prevent destabilization of the rock in the wellbore, and/or at least partially overcome the pressure of fluids inside the rock so that the fluids do not enter the wellbore. Other equipment can also be used for evaluating formations, fluids, production, other operations, and so forth.

### SUMMARY

Aspects of the disclosure can relate to detecting and accounting for fault conditions affecting electronic devices. In implementations, the electronic devices can be coupled to one another in series with a common power line linking the electronic devices together. For example, the electronic devices can include down hole tools/equipment of a drill string.

In embodiments, a system can include circuitry configured to couple a first electronic device with a second electronic device. The circuitry can detect an instantaneous current, an average peak current, and/or an average current flowing from the first electronic device to the second electronic device. The system can further include a switch driven by the circuitry. The circuitry can set the switch to an open position, where the first electronic device and the second electronic device are electrically disconnected from one another, when the instantaneous current, the average peak current, or the average current exceeds a respective predetermined threshold.

In other embodiments, a system can include circuitry configured to couple a first electronic device with a second electronic device, where the circuitry includes a communication module configured to link the circuitry to a master controller. The system can further include a switch driven by the circuitry. The circuitry can set the switch to a closed position, wherein the first electronic device and the second electronic device are electrically connected to one another, after power is furnished to the first electronic device during a first startup sequence. The circuitry can then set the switch to an open position, wherein the first electronic device and the second electronic device are electrically disconnected from one another, when a communication between the circuitry and the master controller indicates a fault condition. The circuitry can also maintain the switch in the open position after power is furnished to the first electronic device during a second startup sequence to avoid furnishing power to an inoperable/malfunctioning device (e.g., the second electronic device) or creating a bad connection (e.g., short) that could potentially harm or disable other devices (e.g., the first electronic device).

A method of detecting and accounting for fault conditions is also disclosed. The method can include powering a first electronic device and attempting to communicate with the first electronic device. After successfully communicating with the first electronic device, a second electronic device can be powered by closing a switch to electrically connect the first electronic device with the second electronic device. This can be done sequentially to power and test one device at a time from a plurality of series coupled devices. After attempting to communicate with the second electronic device, the switch can be opened to electrically disconnect the second electronic device from the first electronic device when communication with the second electronic device is indicative of a fault condition (e.g., unsuccessful/corrupt communication, error message, warning, diagnostic data, or the like).

This summary is provided to introduce a selection of concepts that are further described below in the detailed description. This summary is not intended to identify key or essential features of the claimed subject matter, nor is it intended to be used as an aid in limiting the scope of the claimed subject matter.

### BRIEF DESCRIPTION OF THE DRAWINGS

Embodiments of systems and methods for detecting and accounting for fault conditions affecting electronic devices are described with reference to the following figures. The same numbers are used throughout the figures to reference like features and components.

FIG. 1 illustrates an example system in which embodiments of a system for detecting and accounting for fault conditions affecting electronic devices can be implemented.

FIG. 2 illustrates an example system in which embodiments of a system for detecting and accounting for fault conditions affecting electronic devices can be implemented.

FIG. 3 illustrates an embodiment of a system for detecting and accounting for fault conditions affecting electronic devices.

FIG. 4 illustrates an embodiment of a system for detecting and accounting for fault conditions affecting electronic devices.

FIG. 5 illustrates an embodiment of a system for detecting and accounting for fault conditions affecting electronic devices.

FIG. 6 illustrates a diagnostic system for detecting fault conditions affecting electronic devices that can be implemented in a system for detecting and accounting for fault conditions affecting electronic devices.

FIG. 7 illustrates an example system in which embodiments of a system for detecting and accounting for fault conditions affecting electronic devices can be implemented.

FIG. 8 illustrates an example process for detecting and accounting for fault conditions affecting electronic devices.

### DETAILED DESCRIPTION

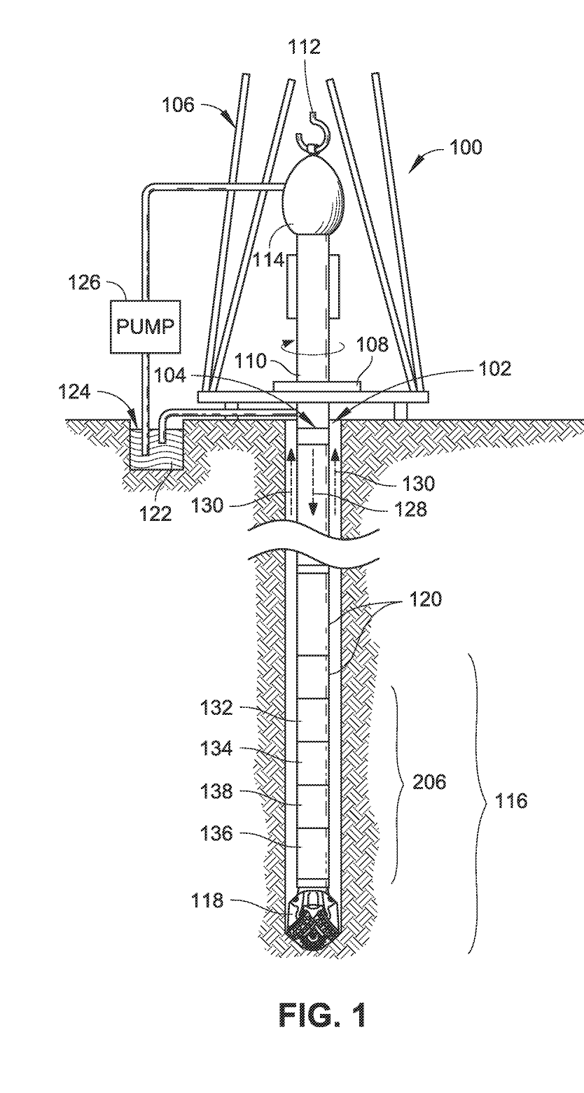

FIG. 1 depicts a wellsite system 100 in accordance with one or more embodiments of the present disclosure. The wellsite can be onshore or offshore. A borehole 102 is formed in subsurface formations by directional drilling. A drill string 104 extends from a drill rig 106 and is suspended within the borehole 102. In some embodiments, the wellsite system 100 implements directional drilling using a rotary steerable system (RSS). For instance, the drill string 104 is rotated from the surface, and down-hole devices move the end of the drill string 104 in a desired direction. The drill rig 106 includes a platform and derrick assembly positioned over the borehole 102. In some embodiments, the drill rig 106 includes a rotary table 108, kelly 110, hook 112, rotary swivel 114, and so forth. For example, the drill string 104 is rotated by the rotary table 108, which engages the kelly 110 at the upper end of the drill string 104. The drill string 104 is suspended from the hook 112 using the rotary swivel 114, which permits rotation of the drill string 104 relative to the hook 112. However, this configuration is provided by way of example and is not meant to limit the present disclosure. For instance, in other embodiments a top drive system is used.

A bottom hole assembly (BHA) 116 is suspended at the end of the drill string 104. The bottom hole assembly 116 includes a drill bit 118 at its lower end. In embodiments of the disclosure, the drill string 104 includes a number of drill pipes 120 that extend the bottom hole assembly 116 and the drill bit 118 into subterranean formations. Drilling fluid (e.g., mud) 122 is stored in a tank and/or a pit 124 formed at the wellsite. The drilling fluid can be water-based, oil-based, and so on. A pump 126 displaces the drilling fluid 122 to an interior passage of the drill string 104 via, for example, a port in the rotary swivel 114, causing the drilling fluid 122 to flow downwardly through the drill string 104 as indicated by directional arrow 128. The drilling fluid 122 exits the drill string 104 via ports (e.g., courses, nozzles) in the drill bit 118, and then circulates upwardly through the annulus region between the outside of the drill string 104 and the wall of the borehole 102, as indicated by directional arrows 130. In this manner, the drilling fluid 122 cools and lubricates the drill bit 118 and carries drill cuttings generated by the drill bit 118 up to the surface (e.g., as the drilling fluid 122 is returned to the pit 124 for recirculation).

In some embodiments, the bottom hole assembly 116 includes down tools, such as a logging-while-drilling (LWD) module 132, a measuring-while-drilling (MWD) module 134, a rotary steerable system 136, a motor, and so forth (e.g., in addition to the drill bit 118). The logging-while-drilling module 132 can be housed in a drill collar and can contain one or a number of logging tools. It should also be noted that more than one LWD module and/or MWD module can be employed (e.g., as represented by another logging-while-drilling module 138). In embodiments of the disclosure, the logging-while drilling modules 132 and/or 138 include capabilities for measuring, processing, and storing information, as well as for communicating with surface equipment, and so forth.

The measuring-while-drilling module 134 can also be housed in a drill collar, and can contain one or more devices for measuring characteristics of the drill string 104 and drill bit 118. The measuring-while-drilling module 134 can also include components for generating electrical power for down-hole tools (e.g., sensors, electrical motors, transmitters, receivers, controllers, energy storage devices, and so forth). For example, the system can include a mud turbine generator (also referred to as a “mud motor”) powered by the flow of the drilling fluid 122. However, this configuration is provided by way of example and is not meant to limit the present disclosure. In other embodiments, other power and/or battery systems can be employed. The measuring-while-drilling module 134 can include one or more of the following measuring devices: a weight-on-bit measuring device, a torque measuring device, a vibration measuring device, a shock measuring device, a stick slip measuring device, a direction measuring device, an inclination measuring device, and so on.

In embodiments of the disclosure, the wellsite system 100 is used with controlled steering or directional drilling. For example, the rotary steerable system 136 is used for directional drilling. As used herein, the term “directional drilling” describes intentional deviation of the wellbore from the path it would naturally take. Thus, directional drilling refers to steering the drill string 104 so that it travels in a desired direction. In some embodiments, directional drilling is used for offshore drilling (e.g., where multiple wells are drilled from a single platform). In other embodiments, directional drilling enables horizontal drilling through a reservoir, which enables a longer length of the wellbore to traverse the reservoir, increasing the production rate from the well. Further, directional drilling may be used in vertical drilling operations. For example, the drill bit 118 may veer off of a planned drilling trajectory because of the unpredictable nature of the formations being penetrated or the varying forces that the drill bit 118 experiences. When such deviation occurs, the wellsite system 100 may be used to guide the drill bit 118 back on course.

Drill assemblies can be used with, for example, a wellsite system (e.g., the wellsite system 100 described with reference to FIG. 1). For instance, a drill assembly can comprise a bottom hole assembly suspended at the end of a drill string (e.g., in the manner of the bottom hole assembly 116 suspended from the drill string 104 depicted in FIG. 1). In some embodiments, a drill assembly is implemented using a drill bit. However, this configuration is provided by way of example and is not meant to limit the present disclosure. In other embodiments, different working implement configurations are used. Further, use of drill assemblies in accordance with the present disclosure is not limited to wellsite systems described herein. Drill assemblies can be used in other various cutting and/or crushing applications, including earth boring applications employing rock scraping, crushing, cutting, and so forth.

A drill assembly includes a body for receiving a flow of drilling fluid. The body comprises one or more crushing and/or cutting implements, such as conical cutters and/or bit cones having spiked teeth (e.g., in the manner of a roller-cone bit). In this configuration, as the drill string is rotated, the bit cones roll along the bottom of the borehole in a circular motion. As they roll, new teeth come in contact with the bottom of the borehole, crushing the rock immediately below and around the bit tooth. As the cone continues to roll, the tooth then lifts off the bottom of the hole and a high-velocity drilling fluid jet strikes the crushed rock chips to remove them from the bottom of the borehole and up the annulus. As this occurs, another tooth makes contact with the bottom of the borehole and creates new rock chips. In this manner, the process of chipping the rock and removing the small rock chips with the fluid jets is continuous. The teeth intermesh on the cones, which helps clean the cones and enables larger teeth to be used. A drill assembly comprising a conical cutter can be implemented as a steel milled-tooth bit, a carbide insert bit, and so forth. However, roller-cone bits are provided by way of example and are not meant to limit the present disclosure. In other embodiments, a drill assembly is arranged differently. For example, the body of the bit comprises one or more polycrystalline diamond compact (PDC) cutters that shear rock with a continuous scraping motion.

In embodiments of the disclosure, the body of a drill assembly can define one or more nozzles that allow the drilling fluid to exit the body (e.g., proximate to the crushing and/or cutting implements). The nozzles allow drilling fluid pumped through, for example, a drill string to exit the body. For example, drilling fluid can be furnished to an interior passage of the drill string by the pump and flow downwardly through the drill string to a drill bit of the bottom hole assembly, which can be implemented using, for example, a drill assembly. Drilling fluid then exits the drill string via nozzles in the drill bit, and circulates upwardly through the annulus region between the outside of the drill string and the wall of the borehole. In this manner, rock cuttings can be lifted to the surface, destabilization of rock in the wellbore can be at least partially prevented, the pressure of fluids inside the rock can be at least partially overcome so that the fluids do not enter the wellbore, and so forth.

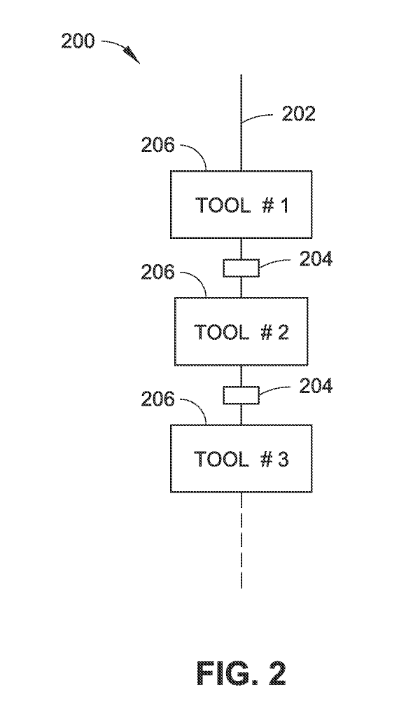

A bottom hole assembly 116 and in other electrical configurations (e.g., sensor/alarm systems), multiple electronic devices can be connected in series with one another. For example, a BHA 116 can include a MWD tool 134 and several LWD tool (e.g., LWD 132 and LWD 138) that are connected by a single wire bus called LTB (Low Power Tool Bus). To further illustrate, FIG. 2 shows a series configuration 200 wherein a single wire bus 202 can power and can also communicatively couple multiple electronic devices/tools 206 (e.g., MWDs, LWDs, various sensors, electrical motors, transmitters, receivers, controllers, other energy storage devices, and so forth). While individual tools may contain operational batteries, tools 206 are often powered by the MWD 134 which may include a turbine that is powered by the pressure of the mud. The MWD 134 is also the communication master of the bus, taking turns to communicate with each tool to acquire their real time data for modulation to the surface. While preparing for a job, field engineers can pick up each tool 206 individually and make a field joint to the tool 206 that is in the slips (in the well). The sequence of tools 206 can be specified by the parameters of the job and the MWD 134 may not be the tool 206 on the top. Once the BHA 116 has been assembled, a field engineer will most likely perform what is called a Shallow Hole Test (SHT) to ensure that the assembled BHA 116 is operational. During the SHT, it is likely that the BHA 116 will be inaccessible to the engineers. The validity of the BHA 116 is confirmed by the field engineer receiving modulated data from the MWD 134.

While the operability of the BHA 116 can be validated by receiving data that is in-range or within expected bounds, errors in the tools 206, extenders, connections, and so forth can cause no data to be received from a particular tool 206 or set of tools 206. In this case, the field engineer may be left to his own resources and creativity to determine where the problem may lie with very little in the way of debug tools and methods. To remedy the situation, a field engineer may lay down each tool one by one, checking the extenders as they do so and attempt to isolate the problem by a trial and error of replacing components and tools. The time that is spent trying to determine where the problem is with such a BHA 116 is classified as non-productive time (NPT). Moreover, in case of a short circuitry in any of the tools 206 the power for the entire BHA 116 may be affected (e.g., total BHA power failure). Aspects of this disclosure are directed to a smart fuse 204 that can be implemented within each tool 206 or placed in series with the tool 206 to detect fault conditions (e.g., short circuit) and disable the affected tool 206. In implementations, the smart fuse 204 can be used with legacy tools and will not require a change in the length of the tool 206 (e.g., length of LWD tool) or the BHA 116. The smart fuse 204 can be installed between the tools 206 in the BHA 116 in the extender area, within the tool 206 itself, or as part of another tool or sub in series with the tool 206 being monitored. Having a smart fuse for each of the tools 206 can protect against a short circuit from any tool 206, but having even a single smart fuse can at least protect part of the BHA 116.

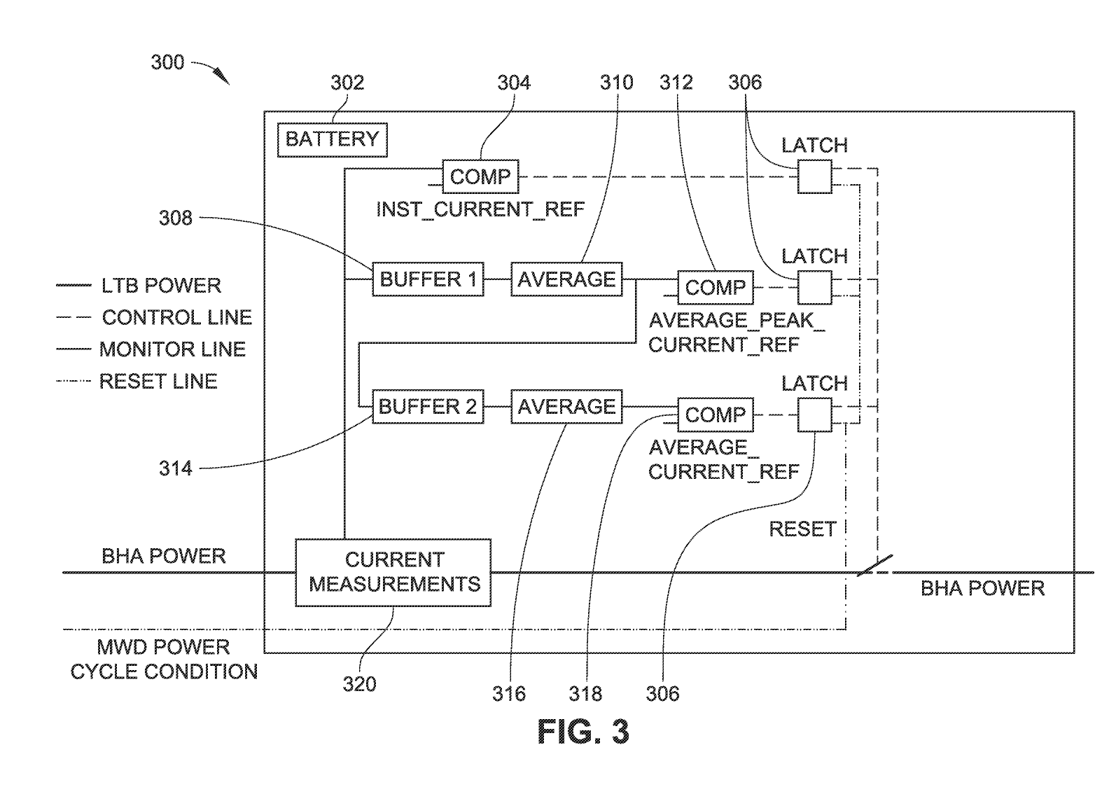

FIGS. 3 through 5 illustrate various embodiments of a system 300 that can implement a smart fuse (e.g., such as smart fuse 204). In embodiments, the system 300 includes circuitry configured to couple a first tool 206 with a second tool 206. The circuitry can detect an instantaneous current, an average peak current, and/or an average current flowing from the first tool 206 to the second tool 206. The system can further include a switch driven by the circuitry. The circuitry can set the switch to an open position, where the first tool 206 and the second tool 206 are electrically disconnected from one another, when the instantaneous current, the average peak current, or the average current exceeds a respective predetermined threshold. In some embodiments, the system 300 can also store the number of times a fault occurred even if the mud pumps are cycled (e.g., LTB power from MWD is cycled). If the number of errors exceeds certain limit, the system 300 can turn off the “other” side of the BHA 116 (e.g., downstream tools 206) until reset by an operator or control system.

The circuitry can include a current detector 320 (e.g., an ammeter) that detects an instantaneous current and a comparator 304 that compares the detected instantaneous current with a respective predetermined threshold value for the instantaneous current. The circuitry can also include a first buffer 308 that stores values of the instantaneous current detected at multiple points in time and an averager 310 that determines an average peak current over a period of time based on the stored values of the instantaneous current detected at multiple points in time. Another comparator 312 coupled to the averager 310 can compare the determined average peak current with the respective predetermined threshold value for the average peak current. In some embodiments, the circuitry can further include a second buffer 314 that stores values of the average peak current determined at multiple points in time and an averager 316 that determines an average current over a period of time based on the stored values of the average peak current detected at multiple points in time. Another comparator 318 coupled to the averager 316 can compare the determined average current with the respective predetermined threshold value for the average peak current. One or more latches 306 or switches can be driven by comparator 304, 312, and/or 318 to break the power connection (e.g., electrically disconnect the first tool 206 and the second tool 206 and any other tools 206 located further downstream) when the instantaneous current, the average peak current, or the average current exceeds a respective predetermined (e.g., programmed) threshold value. In some embodiments, the latches 306 or switches reset when the mud pumps are turned off (e.g., the switch is reset to a closed position).

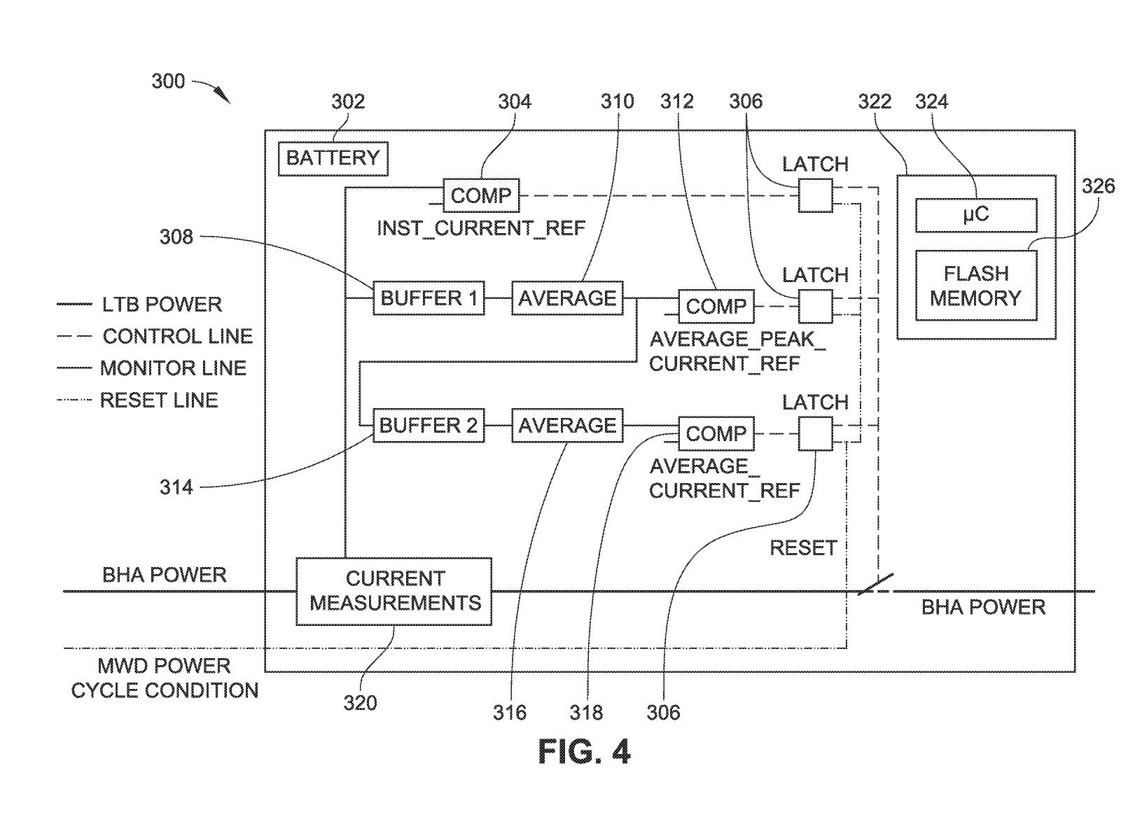

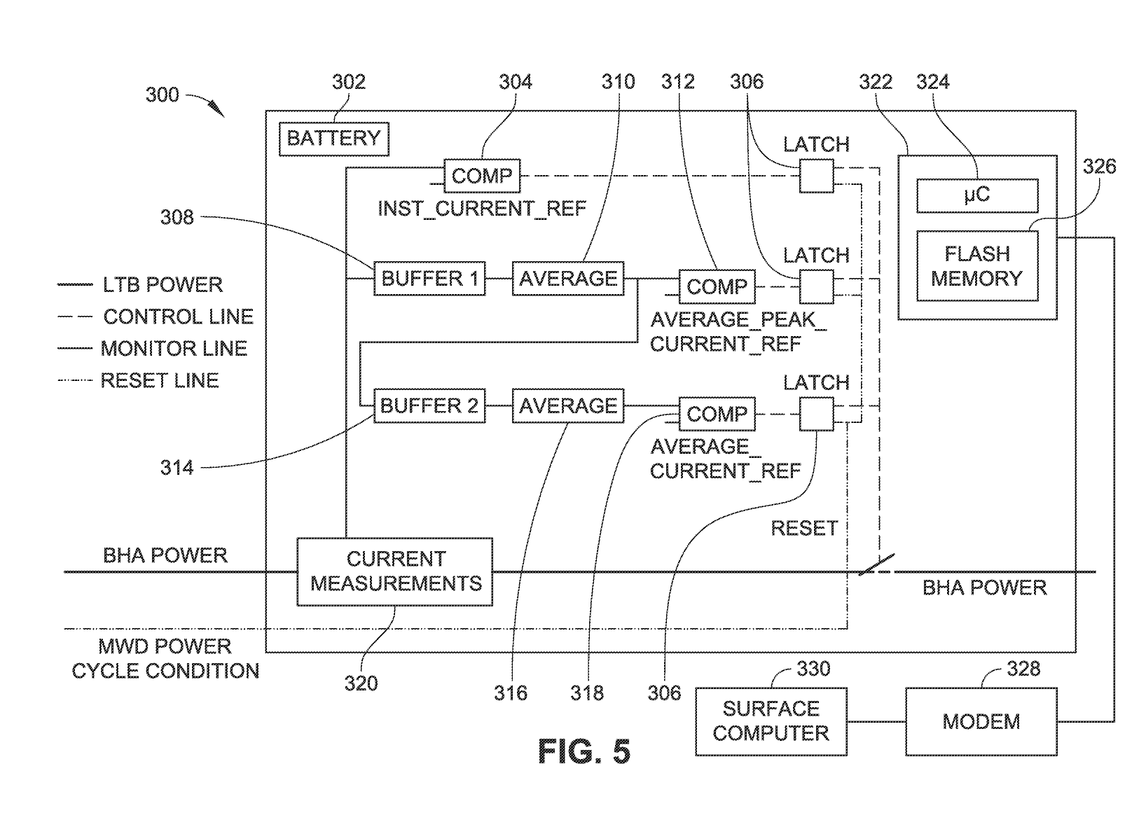

In some embodiments, the system 300 can prevent the BHA 116 or a portion of the BHA 116 from powering up if the number of times the fault has occurred exceeds a certain value. As shown in FIGS. 4 and 5, the system 300 can include a chipset 322 comprising a processor or microcontroller 324 coupled to a memory device 326 (e.g., flash memory). The processor 324 can store data in the memory device 326 regarding a number of times that a fault condition occurred (e.g., the number of times the instantaneous current, the average peak current, and/or the average current exceeded a respective predetermined threshold or simply the number of times the BHA 116 power was turned off). If the recorded number exceeds a certain value, the BHA 116 may be disabled (e.g., switches open) until it is pulled out of hole (POOH) and surface tested. In some embodiments, once this condition is triggered, the switch will not close unless the smart fuse 204 (implementing system 300) is reset once the tool 206 is on surface. In embodiments, the system 300 can include an energy storage device 302 (e.g., battery pack) that furnishes power to the circuitry and/or the chipset 322. As shown in FIG. 5, in further embodiments, the system can include a communication module 328 (e.g., a modem) configured to link the processor or microcontroller 324 to a remotely located computer 330 (e.g., a surface computer), where the remotely located computer 330 can control opening and closing of the smart fuse switch based on the recorded data regarding detected fault conditions.

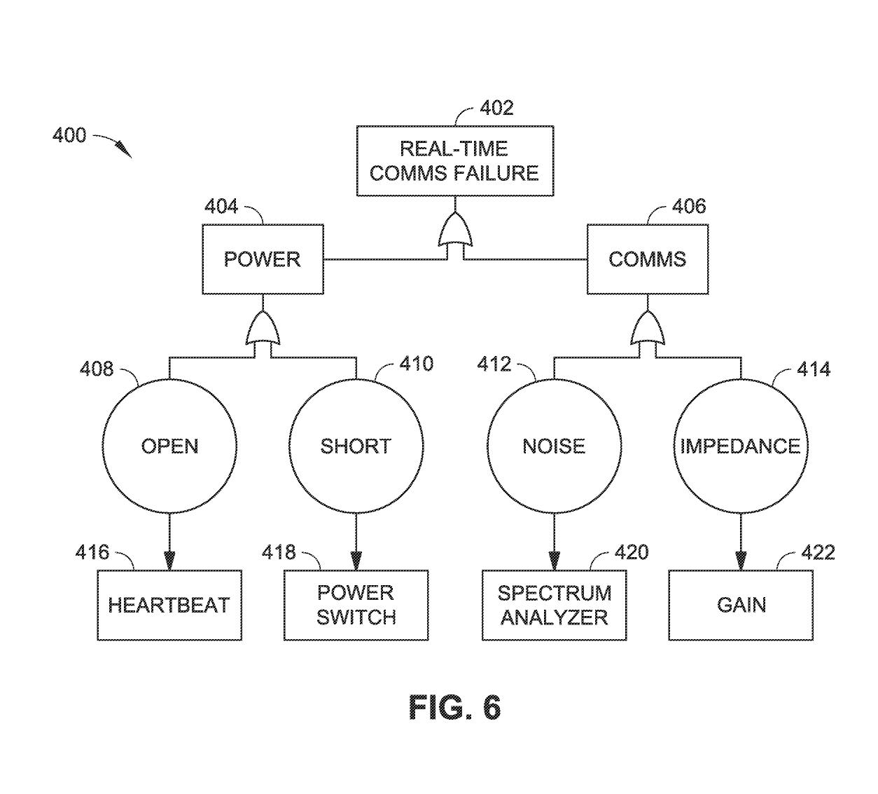

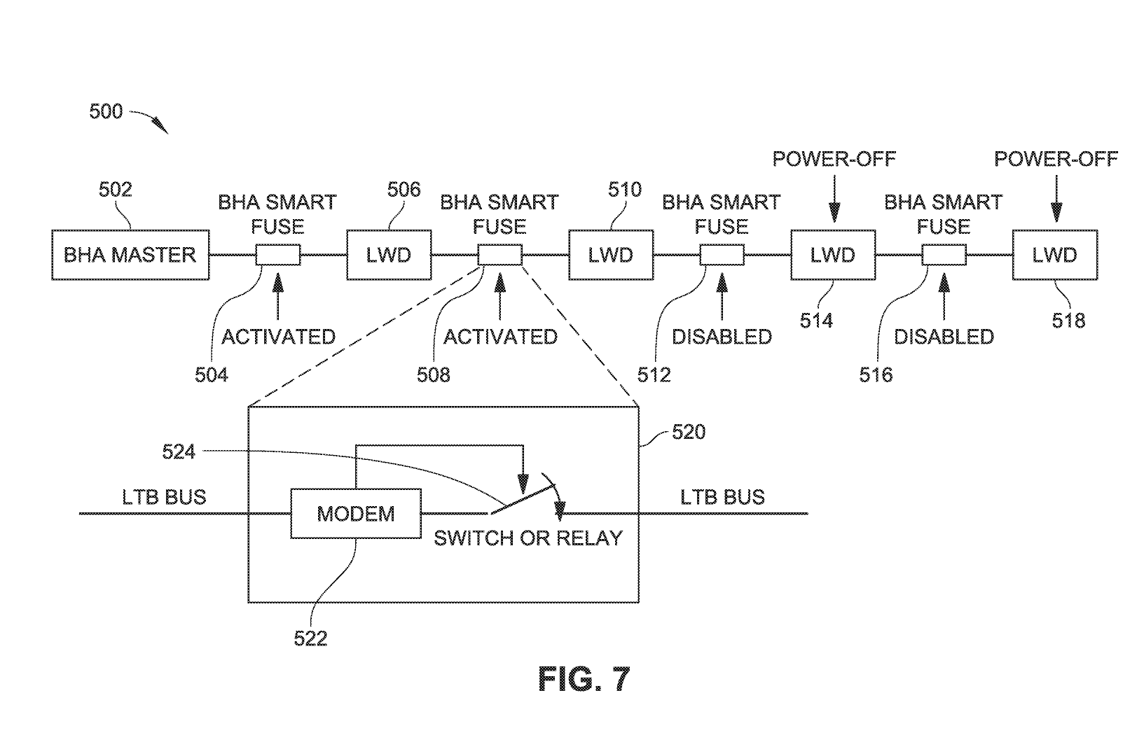

FIGS. 6 and 7 illustrate additional embodiments of systems (e.g., systems 400 and 500) that can implement a smart fuse (e.g., such as smart fuse 204) to automate the discovery of fault conditions and help a field engineer isolate the troubled area, thus reducing the total non-productive time (NPT) that is observed. As shown in FIG. 7, a smart fuse can be inserted in series between tools or built into tools in the BHA, and can have built in communication, processing and storage capabilities along with the capability to break (via a switch or relay) the power and communication channel to the next tool if the next tool is deemed un-operational. For example, a BHA master 502 (e.g., MWD master controller component, BHA bus master controller, or master smart fuse) can be connected to a plurality of series coupled LWD tools (e.g., LWD 506, 510, 514, and 518) having respective smart fuses (e.g., smart fuses 504, 508, 512, and 516) for each of the tools. Each smart fuse can power on to a default state, where its output communication and power channel are disabled. Using such architecture, the BHA master 502 can communicate with each smart fuse (e.g., smart fuses 504, 508, 512, and 516) sequentially to determine if there is a proper power and communication path between the MWD and the smart fuse. If it is determined that a proper channel exists, the smart fuse can open its output channel and allow for the querying of the next tool in the series. In embodiments, this power on sequence can allow the BHA master 502 to help identify and isolate an extender or tool in the series that is misbehaving, allowing the field engineer to hone in on the problem area much quicker, without having to pull up the tool string and individually test each connection.

FIG. 6 illustrates a system 400 that can be implemented within a smart fuse (e.g., smart fuses 504, 508, 512, and 516) to diagnose fault conditions that can affect BHA tools or the like. A detected communication failure 402 can be characterized as a power failure condition 404 or a communication failure condition 406. A power failure condition 404 may arise if there is an open 408 or short 410 on the BHA power path. This can occur when an extender is not properly seated or if there is a fault within the tool itself. If there is no power, it is likely that there will be no communication; however, the tool may be battery powered and still trying to communicate. If the channel is intermittent, the intermittent communications can be mistakenly identified as a fault on the tool or electronics in the tool where in reality the fault may lie in the path itself. In addition to faulty communication paths, there may be signal degradation on the channel which may be adding noise 412 or altering the AC characteristic (e.g., impedance 414) of the channel in such a way the receiver may not make sense of the signal that is being transmitted. To cover these scenarios, the system 400 can include sensors and/or analysis modules run on a processor to breaks down the fault isolation process by power 404 and communication 406 first and then having each fault monitored by an individual sensor or module (e.g., heartbeat sensor 416, power switch 418, spectrum analyzer 420, gain sensor 422, and so forth).

Referring again to FIG. 7, a smart fuse (e.g., smart fuse 504, 508, 512, or 516) can be implemented as a system 520 including a communication module (e.g., a modem or the like) configured to link system control circuitry to the BHA master controller 502. The system 520 implementing the smart fuse can include circuitry or controller logic enabling the smart fuse to communicate on the BHA bus, send and receive test tones in various frequencies, perform a frequency analysis of the AC component of the BHA power and communication path, process and store the foregoing types of information, and convert such information to real time data points. In embodiments, the system 520 includes a processor or microcontroller coupled with a storage device to record data regarding communications or detected fault conditions. Surface communication capability of the system 520 may not be limited to a read out port. Instead, any peripheral can be included that enables interfacing with a surface component (e.g., USB, Ethernet, wireless communication protocols, and the like). The system 520 further includes a switch 524 or relay to break or form the downhole bus (e.g., LTB) connection to the next tool in the series (e.g., connection between LWD 506 and LWD 510).

In embodiments, the system circuitry 520 can set the switch 524 to a closed position, where a first tool (e.g., LWD 506) and a second tool (e.g., LWD 510) are electrically connected to one another, after power is furnished to the first tool (e.g., LWD 506) during a first startup sequence. The second tool (e.g., LWD 510) can be powered after confirming that the second smart fuse (e.g., smart fuse 508) is functioning properly based on communications received by the BHA master 502 from the second smart fuse 508. The system circuitry 520 of the second smart fuse 508 can set or maintain the switch 524 in an open position, where the first tool (e.g., LWD 506) and the second tool (e.g., LWD 510) are electrically disconnected from one another, when a communication between the second smart fuse 508 and the BHA master 502 indicates a fault condition. For example, the communication can indicate a fault condition when the communication is unsuccessful, unstable, or corrupted, or when the communication includes diagnostic information (e.g., sensor information) that is indicative of a fault condition. The system circuitry 520 can maintain the switch 524 in the open position, even after power is furnished to the first tool (e.g., LWD 506), during a second (subsequent) startup sequence based on recorded data associated with the detected fault condition or in response to instructions from the BHA master 502 that are based on the previously detected fault condition. In this manner, the BHA is capable of being at least partially operable without risk of damage to the operable portion of the BHA.

As previously discussed herein, a smart fuse (e.g., smart fuse 504, 508, 512, or 516) can be implemented within an electronic device or tool (e.g., LWD 506, 510, 514, or 518) that is part of a string of series coupled tools; the smart fuse can also be part of an extender that is coupled to a tool terminal; or it can be implemented within a standalone device that is situated between two tools that are in series with one another (e.g., between LWD 506 and LWD 510, as shown in FIG. 7).

Where the smart fuse is implemented in a standalone device, a small tool or sub can be constructed with many capabilities of an LWD tool from the perspective of BHA functionality—in the sense that it will have a node ID, will be able to process and store data, will be able to communicate on the BHA bus (LTB) and may have a read out port or the like to allow for surface access of its recorded mode data. Under this approach, the smart fuse may contain, on its output, a switch or relay that is by default disconnected or open. After the MWD has verified that the power and communication path between it and the smart fuse is valid will the output be opened to allow communication to the next LWD in the path. Accordingly, the BHA master 502 can isolate each tool to test if it is functioning as expected. However, implementing the smart fuse in another device along the BHA string will introduce another extender to the system which can be another potential source of failure.

To avoid the failures that may be introduced by adding more extenders to the system, the smart fuse can be implemented as part of the extender. Using this approach, it is possible to save on total BHA length and cost by adding relatively small circuity to the extender at least part of the smart fuse functionality described herein. It can also be advantageous to integrate a smart fuse within each tool (e.g., within LWD 506, 510, 514, and 518). For example, the smart fuse can be built into the front-end of each LWD, where the smart fuse can be enabled to: power on first; allow for a simple communication and power check; and then power on the rest of the tool and tool chain. However, this solution will have to be applied to existing and legacy tools.

It is also contemplated that two or more of the embodiments described herein can be implemented in a single BHA string depending on which solution is appropriate for the tools being coupled with one another. For example, in cases where a power or communications adapter is placed between two tools, it can be advantageous to integrate a smart fuse within the adapter.

The BHA master 502 or MWD can also implement a specific technique or protocol to communicate with the smart fuses in the BHA 116. Existing MWDs may be modified to include this simple polling architecture to communicate with each tool in turn and report the results in a rotating frame or survey to the surface for use in a SHT. In another embodiment, a separately included BHA master 502 can replace the communication tasks of the MWD. Using this approach, the MWD will communicate with the BHA master 502 which can have additional processing and communication capability to communicate with and monitor the smart fuses in the BHA 116 to collect operational information.

In implementations, the smart fuse can use a communication path of the BHA 116 instead of DC power diagnostics and measurement to infer if a respective tool is in a shorted state. The BHA master 502 can iteratively communicate with each smart fuse, as mentioned before, but in doing so store the last communicated smart fuse identification (smart fuse ID) and count associated with a communication attempt to a non-volatile memory location. If during the enabling of the smart fuse output channel, the channel becomes shorted and the whole system is brought down, the BHA master 502 can compare the smart fuse ID and count of communication attempts. If the count exceeds a certain threshold, the BHA master 502 can stop at the problem node and generate a fault diagnostic to identify the tool or extender with the identified short or other fault condition.

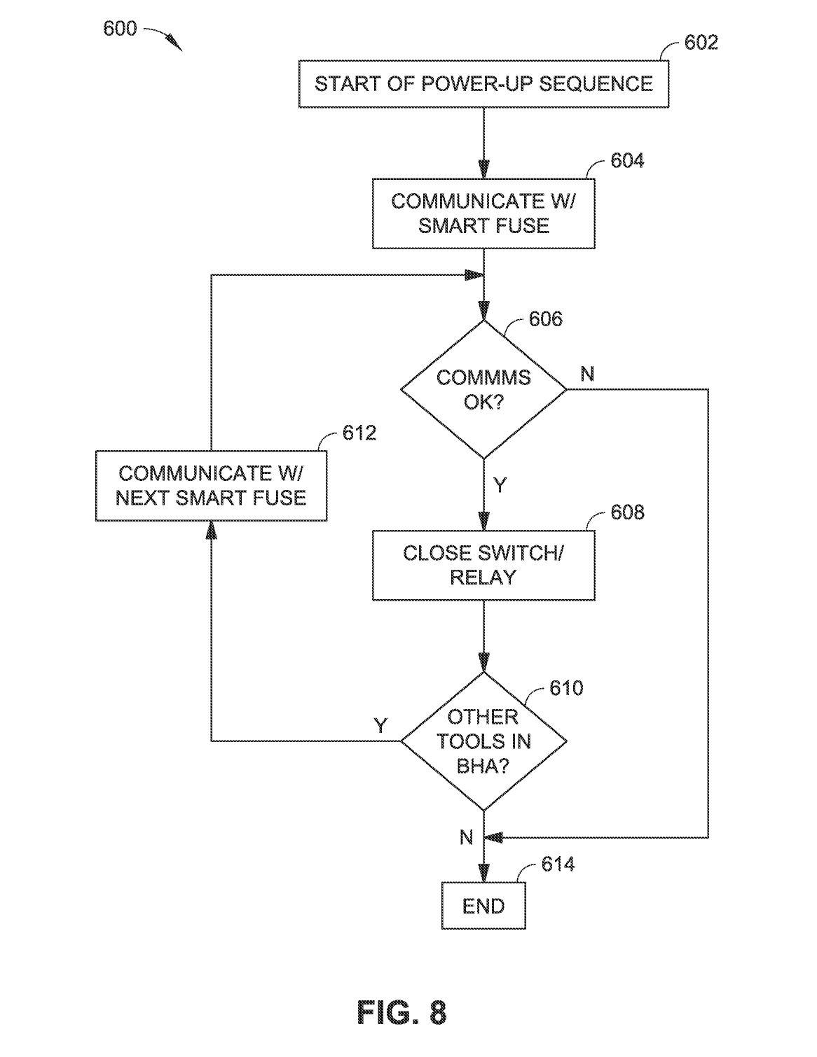

The MWD or the BHA Master 502 can communicate with the smart fuses (e.g., smart fuses 504, 508, 512, and 516) in the BHA 116 in sequence. If the communication succeeds, the smart fuse will allow the connection to the next tool to be made. FIG. 8 is a flow chart illustrating a method 600 that can be used to perform a simple validation of the LWD tools in the BHA sequentially. Method 600 can also be used to detect and account for fault conditions affecting any electronic devices (e.g., sensors, alarms, motors, transmitters, receivers, and so forth) coupled in series with one or more smart fuses placed between the electronic devices.

Referring now to FIG. 8, the method 600 commences a power-up sequence (block 602). For example, power can be furnished to a first electronic device (e.g., smart fuse 504). At block 604, an attempt is made to communicate between BHA Master 502 and the first electronic device (e.g., smart fuse 504) via a communication module (e.g., modem 522). After successfully communicating with the first electronic device (block 606), at block 608, a second electronic device (e.g., LWD 506) is powered on by closing a switch (e.g., switch 524 of smart fuse 504) to electrically connect the first electronic device (e.g., smart fuse 504) with the second electronic device (e.g., LWD 506). In embodiments, tools (e.g., MWDs and LWDs) can have the same communication module (e.g., modem 522). BHA Master 502 establishes a successful communication with the second electronic device (e.g., LWD 506) before it will try to communicate to the next electronic device in the chain (e.g., smart fuse 508). At block 612, an attempt is made to communicate with a third (or next) electronic device (e.g., smart fuse 508) via a communication module (e.g., modem 522). When successful communication is established (block 606) with the third electronic device (e.g., smart fuse 508), a fourth electronic device (e.g., LWD 510) is powered on by closing a switch (e.g., switch 524 of smart fuse 508) to electrically connect the third electronic device (e.g., smart fuse 508) with the fourth electronic device (e.g., LWD 510). Blocks 606 through 612 can be repeated until a fault condition is detected or until each of the tools has been powered on (determined at block 610).

When no communication can be established or where the communication is otherwise indicative of a fault condition affecting the second electronic device (e.g., LWD 510), the smart fuse switch (e.g., switch 524) is opened or maintained in an open position such that the first electronic device (e.g., LWD 506) and the second electronic device (e.g., LWD 510) are electrically disconnected from one another. The method 600 then terminates (block 614). In some embodiments, data is stored or recorded regarding the fault condition or failed communication. At the next power-up sequence (e.g., return to block 602), the smart fuse switch (e.g., switch 524) associated with the detected fault condition or failed communication can be maintained in an open (disconnected) position based on the previously stored data. For example, power will not be furnished to a node associated with a shorted connection to avoid potential failure or interoperability of other tools located upstream from the faulty node.

In some implementations, method 600 is applied during shallow hole testing (SHT), or it can be performed for each power-up, depending on the processing time it takes to allow for the BHA 116 to become active. In addition to a simple communication test, the bus master 502 or MWD may perform the following to gather additional information. Communication Path Diagnostics—during regular operation, the smart fuses may be used to collect information on the BHA 116 that is normally not accessible (e.g., information such as signal to noise ratio of the particular node, the noise generated by the BHA with each individual tool coming online, and so forth). Power Path Diagnostics—the smart fuses may measure the power as seen on the BHA 116 as each tool is powered on and during operations. These logs may be useful in identifying actual issues during field jobs or during tool development. Tool Validity Testing—the capability to communicate through a tool may be assumed if the next tool in the series can be communicated with. However, much of the time, this communication test can occur during a quiet time of the tool (i.e., when the tool is not actually doing anything or acquiring data). Having the smart fuses continually monitor the signals and noise of each node allows for the collection of data that can provide information as to how much a signal degrades going through a tool, how much noise is being injected by the tool in various phases of the tools operation, and can help in identifying any intermittent issues such as an extender not being seated properly.

Although only a few example embodiments have been described in detail above, those skilled in the art will readily appreciate that many modifications are possible in the example embodiments without materially departing from the current disclosure. Features shown in individual embodiments referred to above may be used together in combinations other than those which have been shown and described specifically. Accordingly, all such modifications are intended to be included within the scope of this disclosure as defined in the following claims. In the claims, means-plus-function clauses are intended to cover the structures described herein as performing the recited function and not only structural equivalents, but also equivalent structures. Thus, although a nail and a screw may not be structural equivalents in that a nail employs a cylindrical surface to secure wooden parts together, whereas a screw employs a helical surface, in the environment of fastening wooden parts, a nail and a screw may be equivalent structures. It is the express intention of the applicant not to invoke 35 U.S.C. §112, paragraph 6 for any limitations of any of the claims herein, except for those in which the claim expressly uses the words ‘means for’ together with an associated function.

What is claimed is:

1. A system for detecting and accounting for fault conditions affecting electronic devices of a drill string, comprising:
circuitry configured to couple a first electronic device with a second electronic device, the circuitry being configured to detect at least one of an instantaneous current, an average peak current, or an average current flowing from the first electronic device to the second electronic device; and
a switch driven by the circuitry, the circuitry being configured to set the switch to an open position, wherein the first electronic device and the second electronic device are electrically disconnected from one another, when the at least one of the instantaneous current, the average peak current, or the average current exceeds a respective predetermined threshold.

2. The system as recited in claim 1, wherein the circuitry includes a current detector that detects an instantaneous current.

3. The system as recited in claim 2, wherein the circuitry further includes a comparator that compares the detected instantaneous current with the respective predetermined threshold value for the instantaneous current.

4. The system as recited in claim 2, wherein the circuitry further includes: a first buffer that stores values of the instantaneous current detected at multiple points in time; and an averager that determines an average peak current over a period of time based on the stored values of the instantaneous current detected at multiple points in time.

5. The system as recited in claim 4, wherein the circuitry further includes a comparator that compares the determined average peak current with the respective predetermined threshold value for the average peak current.

6. The system as recited in claim 4, wherein the circuitry further includes: a second buffer that stores values of the average peak current determined at multiple points in time; and an averager that determines an average current over a period of time based on the stored values of the average peak current detected at multiple points in time.

7. The system as recited in claim 6, wherein the circuitry further includes a comparator that compares the determined average current with the respective predetermined threshold value for the average peak current.

8. The system as recited in claim 1, further comprising: a processor coupled to a memory device, the processor storing data in the memory device regarding a number of times that the at least one of the instantaneous current, the average peak current, or the average current exceeded the respective predetermined threshold.

9. The system as recited in claim 8, further comprising an energy storage device that powers the processor and the memory device.

10. The system as recited in claim 8, further comprising a communication module that links the processor to a remotely located computer.

11. A system for detecting and accounting for fault conditions affecting electronic devices of a drill string, comprising:
circuitry configured to couple a first electronic device with a second electronic device, the circuitry including a communication module that links the circuitry to a master controller; and
a switch driven by the circuitry, the circuitry being configured to: set the switch to a closed position, wherein the first electronic device and the second electronic device are electrically connected to one another, after power is furnished to the first electronic device during a first startup sequence; set the switch to an open position, wherein the first electronic device and the second electronic device are electrically disconnected from one another, when a communication between the circuitry and the master controller indicates a fault condition; and maintain the switch in the open position after power is furnished to the first electronic device during a second startup sequence.

12. The system as recited in claim 11, wherein the first electronic device and the second electronic device comprise logging while drilling tools connected in series.

13. The system as recited in claim 12, wherein the master controller is implemented within a measuring while drilling tool connected in series with the logging while drilling tools.

14. The system as recited in claim 11, wherein the master controller stores data associated with the fault condition and provides the circuitry with instruction to maintain the switch in the open position during the second startup sequence based on the stored data.

15. The system as recited in claim 11, wherein at least a portion of the circuitry is implemented within the second electronic device, an extender coupled to the second electronic device, or a tool or sub coupled in between the first electronic device and the second electronic device.

16. A method of detecting and accounting for fault conditions affecting series coupled electronic devices, comprising:
powering a first electronic device;
attempting to communicate with the first electronic device;
after successfully communicating with the first electronic device, powering a second electronic device by closing a switch to electrically connect the first electronic device with the second electronic device;
attempting to communicate with the second electronic device; and
opening the switch to electrically disconnect the second electronic device from the first electronic device when communication with the second electronic device is indicative of a fault condition.

17. The method as recited in claim 16, further comprising:
after successfully communicating with the second electronic device, powering a third electronic device by closing a switch to electrically connect the second electronic device with the third electronic device.

18. The method as recited in claim 16, further comprising:
storing data associated with the fault condition; and
maintaining the switch in the open position during a second startup sequence based upon the stored data.

19. The method as recited in claim 16, wherein the communication with the second electronic device is indicative of the fault condition when the communication with the second electronic device in unsuccessful, unstable, or corrupted.

20. The method as recited in claim 16, wherein the communication with the second electronic device is indicative of the fault condition when the communication includes diagnostic information that is indicative of a fault condition.
